(19) United States
(12) Patent Application Publication
(10) Pub. No.: US 2010/0294350 A1
(43) Pub. Date: Nov. 25, 2010

(54) PHOTO-ELECTRODE COMPRISING CONDUCTIVE NON-METAL FILM, AND DYE-SENSITIZED SOLAR CELL COMPRISING THE SAME

(76) Inventors: Min-Jae KO, Cheonan-si (KR); Won-Mok Kim, Seoul (KR); Kyung-Kon Kim, Chungju-si (KR); Nam-Gyu Park, Daejeon (KR); Boem-Jin Yoo, Seoul (KR); Yong-Hyun Kim, Seoul (KR)

Correspondence Address: North Star Intellectual Property Law, PC, P.O. Box 34688, Washington, DC, 20043, US

(21) Appl. No.: 12/614,459

(22) Filed: Nov. 9, 2009

(30) Foreign Application Priority Data
May 25, 2009 (KR) 10-2009-0045450

(51) Int. Cl. H01L 31/00; H01L 31/18

(52) U.S. Cl. 136/255; 136/256; 438/85; 977/773; 977/954; 257/E21.211

(57) ABSTRACT

Provided are a photo-electrode for dye-sensitized solar cells, and back contact dye-sensitized solar cells comprising the same. The photo-electrode includes a porous membrane having metal oxide nano-particles adsorbed in a photosensitive dye directly contacting a transparent substrate without intermediation of a conductive film, so that the photo-electrode has advanced light transmittance without absorption and scattering of incident light by the conductive film and application possibilities to a thin film retaining a high-level of electrical conductivity, as well as an easy forming method for the conductive film.

### CROSS REFERENCE TO RELATED APPLICATION

The present application claims the benefit under 35 U.S.C. §119(a) of a Korean patent application No. 10-2009-0045450 filed on May 25, 2009, the entire disclosure of which is incorporated herein by reference for all purposes.

### BACKGROUND

(a) Field

The following description relates to photo-electrodes for dye-sensitized solar cells, and back contact dye-sensitized solar cells comprising the same.

(b) Description of the Related Art

As such non-silicon-based solar cells, dye-sensitized solar cells published by Gratzel et al. in 1991 have received particular attention. These dye-sensitized solar cells have a photo-electrode composed of a transparent substrate with a transparent conductive layer formed on a transparent base and a photoelectric conversion layer formed on the transparent conductive layer by carrying a photosensitive dye on semiconductor particles such as metal oxide nano-particles, a counter electrode electrically connected to the photo-electrode, and an electrolyte solution interposed between the photo-electrode and the counter electrode.

In dye-sensitized solar cells, photosensitive dyes absorb incident solar rays and turn to an excited state, thereby transmitting electrons to the conduction band of the metal oxide. The transmitted electrons move to an electrode and flow to an external circuit to transfer electrical energy, and turn to a lower energy state according to the energy transfer and move to the counter electrode. Then, the photosensitive dyes are provided with electrons from the electrolyte solution as much of the dyes transfer to the metal oxide, and turn to the original state, wherein the electrolyte receives electrons from the counter electrode and transfers them to the photosensitive dyes by oxidation-reduction.

The dye-sensitized solar cells are manufactured as a lower cost alternative to silicon solar cells and have gained attention as a next-generation solar cells. However, energy conversion efficiency of the dye-sensitized solar cells is lower than for silicon solar cells, so the dye-sensitized solar cells have been difficult to commercialize.

To improve energy conversion efficiency of the dye-sensitized solar cells, the loss of sunlight reaching the photosensitive dyes should be minimized, the photosensitive dyes should have a wide absorption wavelength range and a high absorption coefficient, and charged dyes should move smoothly to each electrode.

As a dye-sensitized solar cell published by Liyuan Han (Japanese Journal of Applied Physics, Vol. 46, L420, 2007) and J. M. Kroon (Progress in Photovoltaics: Research and Application, Vol. 15, 1, 2007), a photo-electrode comprises a conductive film coated on titanium metal on a metal oxide porous membrane in the opposite direction of incident light, instead of the FTO transparent conductive film applied to a glass substrate in the related art.

However, the above-described dye-sensitized solar cell without absorption and scattering of incident light by the conductive film has a disadvantage that it is difficult for the titanium thin film to guarantee sufficient conductivity, because the titanium thin film is not a porous type. To improve energy conversion efficiency of the dye-sensitized solar cells, the conductive film should be maintained as a porous type on the metal oxide porous membrane to allow smooth movement of the electrolyte to forward electrons to the photosensitive dye.

In addition, a pure metal like titanium usually forms a metal oxide by combining with oxygen, and pure metals have an ionization tendency to become cations by releasing electrons when reacting to chemical compounds in the electrolyte. As a result, electrical conductivity of an electrode falls after the above reactions, and the electrons gathered on the electrode can not effectively flow to the external circuit to transfer electrical energy.

### SUMMARY

According to one general aspect, there is provided a photo-electrode comprising a porous membrane having metal oxide nano-particles adsorbed a photosensitive dye contacted directly with a transparent substrate without intermediation of a transparent electrode such as a conductive film.

According to another aspect, there is provided a photo-electrode for a dye-sensitized solar cell having advanced transmittance without scattering of incident light, that retains a high level of electrical conductivity in the film, and that is a porous type that can have smooth movement of an electrolyte.

According to still another aspect, there is provided a manufacturing method of the photo-electrode comprising a porous membrane having metal oxide nano-particles adsorbed in a photosensitive dye contacted directly with a transparent substrate without intermediation of a transparent conductive film, and the conductive film formed of a conductive non-metal compound.

According to yet another aspect, there is provided a dye-sensitized solar cell including the photo-electrode comprising a porous membrane having metal oxide nano-particles adsorbed in the photosensitive dye contacted directly with a transparent substrate without intermediation of a conductive film, and the conductive film formed of the conductive non-metal compound.

Other features and aspects will be apparent from the following detailed description, the drawings, and the claims.

### BRIEF DESCRIPTION OF THE DRAWINGS

FIG. 1 is a diagram illustrating the structure of an exemplary photo-electrode.

FIGS. 2A and 2B are diagrams illustrating the structure of an exemplary dye-sensitized solar cell comprising a photo-electrode according to an exemplary embodiment.

FIG. 3 is a graph illustrating the result of measuring current-voltage under an AM 1.5G 1 Sun light irradiation condition of a dye-sensitized solar cell according to Example 1 and Comparative Example 1, as further described below.

FIG. 4 is a graph illustrating the result of measuring incident photon to current conversion efficiency (IPCE) of the dye-sensitized solar cell according to Example 1 and Comparative example 1, as further described below.

FIG. 5 is a graph illustrating the result of measuring current-voltage under an AM 1.5G 1 Sun light irradiation condition of the dye-sensitized solar cell according to Example 1 and Comparative example 2, as further described below.

FIG. 6 is a graph illustrating the result of measuring current-voltage under an AM 1.5G 1 Sun light irradiation condition of a dye-sensitized solar cell according to Example 2, as further described below.

Throughout the drawings and the detailed description, unless otherwise described, the same drawing reference numerals will be understood to refer to the same elements, features, and structures. The relative size and depiction of these elements may be exaggerated for clarity, illustration, and convenience.

### EXPLANATIONS OF REFERENCE NUMERALS OF DRAWINGS

| | |
|---|---|
| 10: photo-electrode | 11: transparent substrate |
| 12, 52, 62: porous membrane | 13, 53, 63: conductive film |
| 20: counter electrode | 21: transparent conductive substrate |
| 22: catalyst layer | 23: fine hole |
| 30: electrolyte | 40: polymer layer |

### DETAILED DESCRIPTION

The following detailed description is provided to assist the reader in gaining a comprehensive understanding of the methods, apparatuses, and/or systems described herein. Accordingly, various changes, modifications, and equivalents of the systems, apparatuses and/or methods described herein will be suggested to those of ordinary skill in the art. Also, descriptions of well-known functions and constructions may be omitted for increased clarity and conciseness.

According to one aspect, there is provided a photo-electrode of a dye-sensitized solar cell comprising a porous membrane having metal oxide nano-particles adsorbed in a photosensitive dye contacted directly with a transparent substrate without intermediation of a conductive film, and the conductive film formed of a conductive non-metal compound. For example, the photo-electrode comprises a transparent substrate, a porous membrane having metal oxide nano-particles adsorbed in the photosensitive dye, and a conductive non-metal film, wherein the porous membrane is laminated and contacted between the transparent substrate and the conductive non-metal film.

In the photo-electrode for a dye-sensitized solar cell according to an exemplary embodiment, the photo-electrode comprises the transparent substrate, the porous membrane comprising the metal oxide nano-particles absorbed dyes that is formed on a partial part or the total surface of the transparent substrate, and the conductive non-metal film formed on the porous membrane or on the porous membrane and the transparent substrate.

The transparent substrate may be one used commonly in the art, and may be manufactured of a polymer, glass, or modified organic silicate and the like. Therefore, the transparent substrate used in the photo-electrode may be a transparent plastic substrate or transparent glass substrate.

For example, the transparent substrate may be manufactured of a polymer that may be at least one selected from the group consisting of polyethylene terephthalate (PET), polyethylenenaphthalate (PEN), polycarbonate (PC), polypropylene (PP), polyimide (PI), tri-acetylcellulose (TAC), and polyethersulfone.

Also, the transparent substrate may be used a modified organic silicate having a 3-D network structure prepared by a hydrolysis and condensation reaction of an organic metal alkoxide that may be at least one selected from the group consisting of methyltriethoxysilane (MTES), ethyltriethoxysilane (ETES), and propyltriethoxysilane (PTES).

At the porous membrane having the metal oxide nano-particles adsorbed in the photosensitive dye, photosensitive dyes absorb incident solar rays and turn to an excited state, thereby transmitting electrons. The transmitted electrons move to an electrode and flow to an external circuit to transfer electrical energy. There is no special restriction on the photosensitive dye and the metal oxide nano-particles as long as the photosensitive dye and the metal oxide nano-particles may be used in dye-sensitized solar cells.

Examples of the metal oxide comprised in the porous membrane may be use at least one selected from the group consisting of titanium oxide, zirconium oxide, strontium oxide, zinc oxide, indium oxide, lanthanum oxide, vanadium oxide, molybdenum oxide, tungsten oxide, tin oxide, niobium oxide, magnesium oxide, aluminum oxide, yttrium oxide, scandium oxide, samarium oxide, gallium oxide, and strontium titanium oxide. However, it is not limited to the above-mentioned materials.

The average particle diameter of the metal oxide nano-particles can be determined considering sunlight absorption power, catalytic action (oxidation-reduction reaction), and electrical conductivity, and may be 1 to 500 nm, or 5 to 50 nm as another example.

There is no special restriction on the photosensitive dye as long as it can absorb visible rays. The photosensitive dye may have band gap energy of 1.55 to 3.1 eV. Examples of the photosensitive dye for use can comprise an organic-inorganic complex dye, an organic dye, and mixtures thereof. The organic-inorganic complex dye may be at least one selected from the group consisting of aluminum (Al), platinum (Pt), palladium (Pd), europium (Eu), lead (Pb), iridium (Ir), ruthenium (Ru), and complexes thereof.

The conductive non-metal film (13) may function as transparent electrode of a photo-electrode. The conductive film (13) may be formed on the porous membrane (12) or the transparent substrate (11). The conductive film (13) may be a conductive ceramic film. The conductive film (13) may be a porous type that can retain a high level of electrical conductivity in the film and have smooth movement of electrolyte. According to an aspect, a photo-electrode is provided for a dye-sensitized solar cell excluding the conventional transparent conductive film (ITO, FTO, ZnO—Ga₂O₃, ZnO—Al₂O₃, and SnO₂—Sb₂O₃) applied to the transparent substrate in the related art.

The average thickness of the conductive film (13) can be determined considering smooth movement of the electrolyte forwarding electrons to the photosensitive dye, and may be 1 to 1000 nm.

The components of the conductive non-metal film (ceramic film) may use material that have sufficient conductivity for flowing electrons formed in the porous membrane absorbed by photosensitive dyes to an external circuit and transmitting an electric energy, chemical resistance for various chemicals to an electrolyte, and no influence on performance of the dye-sensitized solar cells.

For example, the conductive non-metal film may be include at least one selected from the group consisting of metal nitrides, metal carbides, metal borides, metal oxides, carbon compounds, and conductive polymers, but, it is not limited to the above-mentioned materials.

The metal nitrides may be at least one selected from the group consisting of group IVB metal nitrides such as titanium nitride, zirconium nitride, and hafnium nitride; group VB metal nitrides such as niobium nitride, tantalum nitride, and vanadium nitride; group VIB metal nitrides such as chromium nitride, molybdenum nitride, and tungsten nitride; aluminum nitride; gallium nitride; indium nitride; silicon nitride; and germanium nitride. For example, the metal nitrides may be at least one selected from the group consisting of titanium nitride, zirconium nitride, hafnium nitride, niobium nitride, tantalum nitride, vanadium nitride, chromium nitride, molybdenum nitride, tungsten nitride, aluminum nitride, gallium nitride, indium nitride, silicon nitride, and germanium nitride.

The metal nitrides may be mixed with a small amount of oxygen or fluorine to achieve higher performances in terms of electrical, optical, or mechanical characteristics, as well as durability and environmental resistance. At this time, the atomic ratio of O₂/(N₂+O₂), F₂/(N₂+F₂), or (O₂+F₂)/(N₂+O₂+F₂) may be 0.2 or less to prevent degradation of characteristics due to excessive generation of oxides or fluorides.

The metal oxides may comprise at least one selected from the group consisting of tin oxide, stibium-doped tin oxide, niobium-doped tin oxide, fluorine-doped tin oxide, indium oxide, tin-doped indium oxide, zinc oxide, aluminum-doped zinc oxide, boron-doped zinc oxide, gallium-doped zinc oxide, hydrogen-doped zinc oxide, indium-doped zinc oxide, yttrium-doped zinc oxide, titanium-doped zinc oxide, silicon-doped zinc oxide, tin-doped zinc oxide, magnesium oxide, cadmium oxide, a magnesium-zinc (Mg—Zn) composite oxide, an indium-zinc (In—Zn) composite oxide, a copper-aluminum (Cu—Al) composite oxide, silver oxide, gallium oxide, a zinc-tin (Zn—Sn) composite oxide, titanium oxide (TiO₂), a zinc-indium-tin (Zn—In—Sn) composite oxide, nickel oxide, rhodium oxide, ruthenium oxide, iridium oxide, copper oxide, cobalt oxide, and tungsten oxide.

The metal carbides may be at least one selected from the group consisting of group IVB metal carbides such as titanium carbide, zirconium carbide, and hafnium carbide; group VB metal carbides such as niobium carbide, tantalum carbide, and vanadium carbide; group VIB metal carbides such as chromium carbide, molybdenum carbide, and tungsten carbide; aluminum carbide; gallium carbide; indium carbide; silicon carbide; and germanium carbide. The metal carbides may comprise at least one selected from the group consisting of titanium carbide, zirconium carbide, hafnium carbide, niobium carbide, tantalum carbide, vanadium carbide, chromium carbide, molybdenum carbide, tungsten carbide, aluminum carbide, gallium carbide, indium carbide, silicon carbide, and germanium carbide. The metal borides may be at least one selected from the group consisting of group IVB metal borides such as titanium boride, zirconium boride, and hafnium boride; group VB metal borides such as niobium boride, tantalum boride, and vanadium boride; group VIB metal borides such as chromium boride, molybdenum boride, and tungsten boride; aluminum boride; gallium boride; indium boride; silicon boride; and germanium boride. The metal borides may comprise at least one selected from the group consisting of titanium boride, zirconium boride, hafnium boride, niobium boride, tantalum boride, vanadium boride, chromium boride, molybdenum boride, tungsten boride, aluminum boride, gallium boride, indium boride, silicon boride, and germanium boride.

The carbon compounds may be at least one selected from the group consisting of activated carbon, graphite, carbon nanotubes, carbon black, and graphene.

The conductive polymers may comprise at least one selected from the group consisting of poly(3,4-ethylenedioxythiophene)-poly(styrenesulfonate) (PEDOT-PSS), polyaniline-camphorsulfonic acid (Polyaniline-CSA, Polyaniline films prepared via the camphorsulfonic acid), pentacene, polyacetylene, poly(3-hexylthiophene)(P3HT), polysiloxane carbazole, polyaniline, polyethylene oxide, poly(1-methoxy-4-(O-disperse red 1)-2,5-phenylene-vinylene), polyindole, polycarbazole, polypyridazin, polyisothianaphthalene, polyphenylene sulfide, polyvinylpyridine, polythiophen, polyfluorene, polypyridine, polypyrrole, polysulfur nitride, and copolymers thereof.

As the exemplary photo-electrode comprises the conductive ceramic film formed on the porous membrane comprising the metal oxide, the dye-sensitized solar cells can fabricate by excluding the conventional transparent conductive film (ITO, FTO, ZnO—Ga₂O₃, ZnO—Al₂O₃, and SnO2-Sb2O3). Moreover, the photo-electrode has superior light transmittance without absorption and scattering of incident light by the conductive film, and application possibilties to a thin film retaining a high-level of electrical conductivity, as well as an easy forming method for the conductive film.

According to another aspect, there is provided a manufacturing method of a photo-electrode for a dye-sensitized solar cell, the method comprising preparing a transparent substrate for a photo-electrode, forming a porous membrane having metal oxide nano-particles on part or the total surface of the transparent substrate, forming a conductive non-metal film on the porous membrane or on the porous membrane and the transparent substrate, and absorbing photosensitive dye on the porous membrane.

The forming of the porous membrane may be conducted by coating a metal oxide nano-particle paste comprising the metal oxide nano-particles, a binder resin, and a solvent on the transparent substrate, and heat-treating the same at 400 to 550° C. for 10 to 120 minutes to form the porous membrane. The average particle diameter of the metal oxide nano-particles may be 1 to 500 nm, or 5 to 50 nm as another example.

The forming of the conductive non-metal film on the porous membrane or on the porous membrane and the transparent substrate may be use the method selected from the group consisting of sputter deposition, cathodic arc deposition, evaporation, e-beam evaporation, chemical vapor deposition, atomic layer deposition, electrochemical deposition, spin coating, spray coating, doctor blade coating, or screen printing to form the conductive non-metal film (ceramic film) on the porous membrane having the metal oxide. The average thickness of the conductive non-metal film may be 1 to 1000 nm.

The absorbing of the photosensitive dye on the porous membrane may be conducted by immersing the transparent substrate formed of the porous membrane and the conductive non-metal film in a solution comprising the photosensitive dye for 1 to 48 hours, so as to absorb the photosensitive dye on the surface of the porous membrane.

According to still another aspect, there is provided a dye-sensitized solar cell comprising the photo-electrode as mentioned, a counter electrode arranged so as to face the photo-electrode, and an electrolyte filled between the photo-electrode and the counter electrode.

Accordingly, a dye-sensitized solar cell may be provided that retains a high level of electrical conductivity by comprising the above-described exemplary photo-electrode comprising the conductive film formed of the conductive non-metal compound and the porous membrane, and has smooth movement of electrolyte, compared to a general metal in the related art.

In addition, the photo-electrode comprising the porous membrane contacted directly on the transparent substrate may be prepared without intermediation of the conductive film, compared to a conventional photo-electrode comprising the porous membrane arranged with intermediation of the conductive film formed on the transparent substrate.

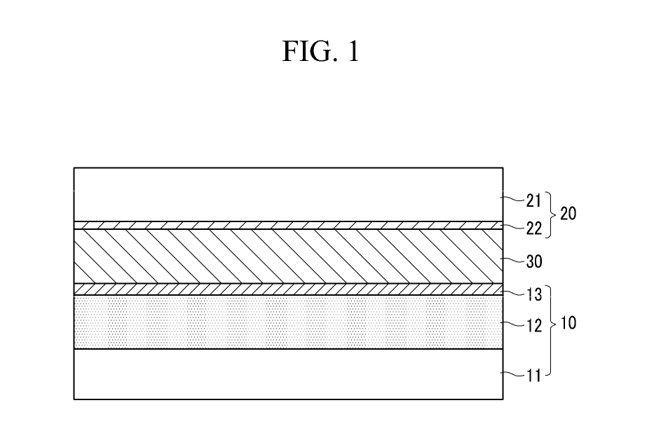

FIG. 1 illustrates a photo-electrode for a dye-sensitized solar cell according to an exemplary embodiment. As shown in FIG. 1, the photo-electrode may comprise the porous membrane (12) arranged between the transparent substrate (11) and the conductive film (13).

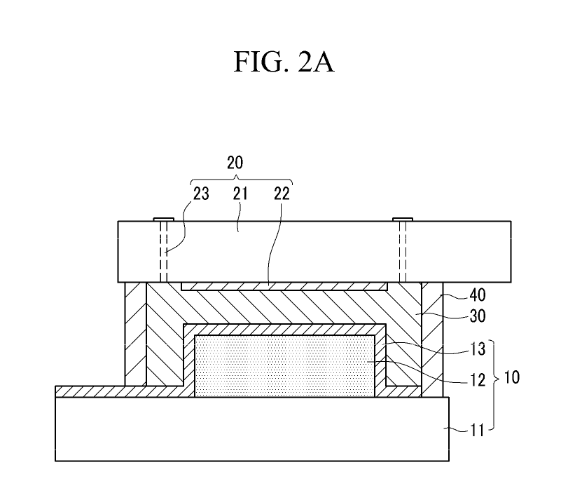

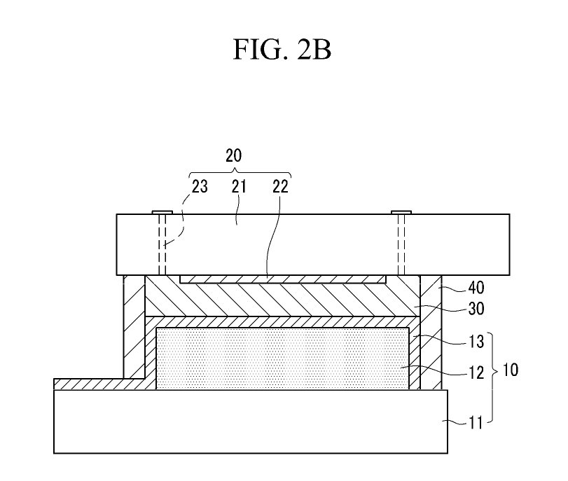

FIGS. 2A and 2B show the structure of a dye-sensitized solar cell comprising the photo-electrode according to an exemplary embodiment.

As shown in FIG. 2A, the dye-sensitized solar cell may comprise the photo-electrode that comprises the transparent substrate (11); the porous membrane (12) having metal oxide nano-particles adsorbed in the photosensitive dye formed on a partial surface of the transparent substrate; and the conductive non-metal film (13) formed on the porous membrane and the transparent substrate.

As shown in FIG. 2B, in another embodiment, the dye-sensitized solar cell may comprise the photo-electrode that includes the transparent substrate (11); the porous membrane (12) having the metal oxide nano-particles adsorbed in the photosensitive dye formed on the total surface of the transparent substrate; and the conductive non-metal film (13) formed on the porous membrane.

Thus, there is provided a dye-sensitized solar cell comprising the photo-electrode (10), a counter electrode (20) arranged so as to face the photo-electrode, and an electrolyte (30) filled between the photo-electrode and the counter electrode through a fine hole (23). The dye-sensitized solar cell is characterized by comprising the photo-electrode which is orderly laminated the porous membrane (12) and the ceramic film (13) on the transparent substrate (11) for the photo-electrode, or the photo-electrode prepared by the mentioned method. In addition, the photo-electrode and the counter electrode can adhere by using the polymer layer (40) including a general adhesive resin to seal between the photo-electrode and the counter electrode.

The electrolyte (30), although shown as one layer in FIG. 1 for convenience, is practically uniformly dispersed in a metal oxide nano-particle layer of the porous membrane (12) between the photo-electrode (10) and the counter electrode (20).

The electrolyte (30) comprise redox derivatives forwarding electrons from the counter electrode (20) to the photosensitive dye in the photo-electrode (10) by oxidation-reduction reactions. There is no special restriction on the redox derivatives as long as the redox derivatives may be used in dye-sensitized solar cells. Examples of the redox derivatives for use is at least one selected from the group consisting of electrolyte including iodine (I), bromine (Br), cobalt (Co), thiocyanate (SCN—), and selenocyanate (SeCn-).

The electrolyte comprises a liquid electrolyte, a gel electrolyte, or a solid electrolyte. Specific examples of the gel electrolyte comprise polymer gel electrolytes such as an electrolyte containing polyvinylidenefluoride-co-polyhexafluoropropylene (PVDF-HFP), polyacrylonitrile (PAN), polyethylene oxide (PEO), and polyalkylacrylate. The ionic gel electrolytes may be use inorganic particles such as silica nano-particles or titanium dioxide nano-particles.

The counter electrode (20) comprises a catalyst layer (22) formed on a transparent conductive substrate (21). The catalyst layer (22) may comprise at least one selected from the group consisting of platinum (pt), activated carbon, graphite, carbon nanotubes, carbon black, a p-type semiconductor, poly(3,4-ethylenedioxythiophene)-poly(styrenesulfonate)(PEDOT-PSS), polyaniline-camphorsulfonic acid (Polyaniline-CSA, Polyaniline films prepared via the camphorsulfonic acid), pentacene, polyacetylene, poly(3-hexylthiophene)(P3HT), polysiloxane carbazole, polyaniline, polyethylene oxide, poly(1-methoxy-4-(0-disperse red 1)-2,5-phenylene-vinylene), polyindole, polycarbazole, polypyridazin, polyisothianaphthalene, polyphenylene sulfide, polyvinylpyridine, polythiophen, polyfluorene, polypyridine, polypyrrole, polysulfur nitride, derivatives thereof, copolymers thereof and complexes of thereof.

The structure of the exemplary photo-electrode and its manufacturing method will be explained with reference to FIG. 1.

According an exemplary embodiment, the first step is preparing a transparent substrate (11) for a photo-electrode. The transparent substrate (11) may use at least one selected from the group consisting of transparent plastic substrates and a transparent glass substrate.

Subsequently, the second step is forming a porous membrane (12) having metal oxide nano-particles on part or the total surface of the transparent substrate (11).

The second step is conducted by coating the metal oxide nano-particle paste comprising the metal oxide nano-particles, binder resin, and solvent on the transparent substrate (11), and performing a heat treatment. The metal oxide nano-particles in the porous membrane (12) perform catalytic action (oxidation-reduction reaction) and electrical conduction during sunlight absorption.

There is no special restriction on the binder resin and solvent in the metal oxide nano-particle paste as long as the binder resin and solvent may be used in dye-sensitized solar cells.

The metal oxide nano-particle paste is prepared by mixing the metal oxide nano-particles with the solvent to form a colloidal solution, and removing the solvent with an evaporator to have general viscosity range. There is no special restriction on the ingredient range of contents as long as the ingredient range may be used in dye-sensitized solar cells.

For example, the metal oxide nano-particle paste is prepared by mixing metal oxide nano-particles with a solvent to form a colloidal solution with a viscosity of 5×10⁴ to 5×10⁵ cps comprising the metal oxide dispersed therein, and adding a binder resin thereto, and then removing the solvent at 40 to 70° C. for 30 minutes to 1 hour with a rotor evaporator.

Forming a porous membrane may be conducted by coating the metal oxide nano-particle paste on the transparent glass substrate, and heat-treating the same at 400 to 550° C. for 10 to 120 minutes.

There is no special restriction on a method for forming the conductive film on the porous membrane, and a known technique such as sputter deposition, cathodic arc deposition, evaporation, e-beam evaporation, chemical vapor deposition, atomic layer deposition, electrochemical deposition, spin coating, spray coating, doctor blade coating, or screen printing may be used.

As mentioned, the exemplary photo-electrode (10) comprises the porous membrane (12) having metal oxide nano-particles adsorbed in the photosensitive dye contacted directly with the transparent substrate (11) without intermediation of the conductive film (13), so that the photo-electrode retains a high level of electrical conductivity and can have smooth movement of electrolyte. The photo-electrode can exclude the conventional transparent conductive film (ITO, FTO, ZnO—Ga₂O₃, ZnO—Al₂O₃, and SnO₂—Sb₂O₃), so that the photo-electrode has advanced light transmittance without scattering of incident light.

A manufacturing method of the dye-sensitized solar cell may comprise the steps of preparing the above-described photo-electrode (10), arranging separately prepared the catalyst layer (22) of the counter electrode (20) so as to face the photo-electrode, and filling an electrolyte (30) between the photo-electrode and the counter electrode.

### EXAMPLES

While examples are provided below, it is understood that such examples are for illustrative purpose only and that embodiments are not limited thereto.

### Example 1

### Preparation of Photo-Electrode

First, as a substrate, a transparent glass substrate (thickness: 2 mm) was prepared. Afterward, a metal oxide nano-particle paste comprising 10 g of titanium oxide nano-particles (average particle diameter: 20 nm), 3 g of binder resin (ethyl cellulose), 1 g of dispersant (lauric acid), and 40 g of solvent (terpineol) was coated on the substrate using a doctor blade. Following this, the substrate was heat-treated at 500° C. for 30 minutes, so a porous membrane having titanium oxide nano-particles was formed on the substrate.

Thereafter, a TiN conductive ceramic film was deposited to an average thickness of 100 nm on the substrate by using magnetron sputtering. While maintaining base pressure of the chamber to 5.0×10⁻⁷ Torr or less, the volume ratio of N₂/(N₂+Ar) was adjusted to mix pure Ar gas and N₂ gas. An experiment was performed with the Ar gas atmosphere with the addition of N₂ at 3 vol %, process pressure of 1 mTorr, a substrate temperature of room temperature, a target power of 80 W, and a fixed distance between the target and the substrate of 6.6 cm.

Subsequently, the substrate was immersed in an ethanol solution comprising 0.3 mM of [Ru(4,4′-dicarboxy-2,2′-bipyridine)₂(NCS)₂] as a photosensitive dye for 12 hours to adsorb the photosensitive dye to the surface of the porous membrane so as to prepare the photo-electrode.

(Preparation of Counter Electrode)

A glass substrate coated by FTO was prepared as the substrate for the counter electrode. After masking the conductive face of the substrate by using an adhesive tape in an area of 1.5 cm², a H₂PtCl₆ solution was coated thereon by using a spin coater, and it was heat-treated at 400° C. for 20 minutes so as to prepare the counter electrode.

(Injection of Electrolyte, Sealing)

The above-prepared photo-electrode and counter electrode were bonded, and then acetonitrile electrolyte comprising PMII (1-methyl-3-propylimidazolium iodide, 0.7M) and I₂(0.03M) was injected therebetween, and sealed to prepare a dye-sensitized solar cell.

### Example 2

### Preparation of Photo-Electrode

First, as a substrate, a transparent glass substrate (thickness: 2 mm) was prepared. Afterward, a metal oxide nano-particle paste comprising 10 g of titanium oxide nano-particles (average particle diameter: 20 nm), 3 g of binder resin (ethyl cellulose), 1 g of dispersant (lauric acid), and 40 g of solvent (terpineol) was coated on the substrate using a doctor blade. Following this, the substrate was heat-treated at 500° C. for 30 minutes, so a porous membrane having titanium oxide nano-particles was formed on the substrate.

Thereafter, a conductive oxide nano-particle paste comprising 12 g of tin-doped indium oxide nano-particles (average particle diameter: 21 nm), a dispersion mixture (ethylene glycol, 2 g, diethylene glycol monobutylether, 2 g, 3,6,9-trioxadecanoic acid, 1 g) and 2 g of solvent (EtOH, anhydrous) was coated on the porous membrane using spin-coating. Following this, the substrate was heat-treated at 600° C. for 30 minutes, so a conductive film was formed.

Subsequently, the substrate was immersed in an ethanol solution comprising 0.3 mM of [Ru(4,4′-dicarboxy-2,2′-bipyridine)₂(NCS)₂] as a photosensitive dye for 12 hours to adsorb the photosensitive dye to the surface of the porous membrane so as to prepare the photo-electrode.

(Preparation of Counter Electrode)

A glass substrate coated by FTO was prepared as the substrate for the counter electrode. After masking the conductive face of the substrate by using an adhesive tape in an area of 1.5 cm², a H₂PtCl₆ solution was coated thereon by using a spin coater, and it was heat-treated at 400° C. for 20 minutes so as to prepare the counter electrode.

(Injection of Electrolyte, Sealing)

The above-prepared photo-electrode and counter electrode were bonded, and then an acetonitrile electrolyte comprising PMII (1-methyl-3-propylimidazolium iodide, 0.7M) and I₂ (0.03M) was injected therebetween, and sealed to prepare a dye-sensitized solar cell.

### Comparative Example 1

A dye-sensitized solar cell was obtained in the same manner as in Example 1, except that the conductive film was formed with Ti metal instead of TiN ceramic.

At this time, the Ti film was deposited to an average thickness of 100 nm on the substrate using RF magnetron sputtering. While maintaining base pressure of the chamber to 5.0×10⁻⁷ Torr or less, an experiment was performed with an Ar gas atmosphere, a process pressure of 1 mTorr, a substrate temperature of room temperature, a target power of 80 W, and the fixed distance between the target and the substrate of 6.6 cm.

### Comparative Example 2

A comparative dye-sensitized solar cell having a general structure that used a transparent conductive glass substrate (FTO) as a photo-electrode was manufactured.

First, a metal oxide nano-particle paste comprising titanium oxide nano-particles (average particle diameter: 20 nm), binder resin (ethyl cellulose), and solvent (terpineol) was coated on the substrate using a doctor blade. Following this, the substrate was heat-treated at 500° C. for 30 minutes, so a porous membrane having titanium oxide nano-particles was formed on the substrate.

Subsequently, the substrate was immersed in an ethanol solution comprising 0.3 mM of [Ru(4,4′-dicarboxy-2,2′-bipyridine)₂(NCS)₂] as a photosensitive dye for 12 hours to adsorb the photosensitive dye to the surface of the porous membrane so as to prepare the photo-electrode.

Preparation of the counter electrode and injection of the electrolyte and sealing were conducted in the same manner as in Example 1.

### Experiment 1

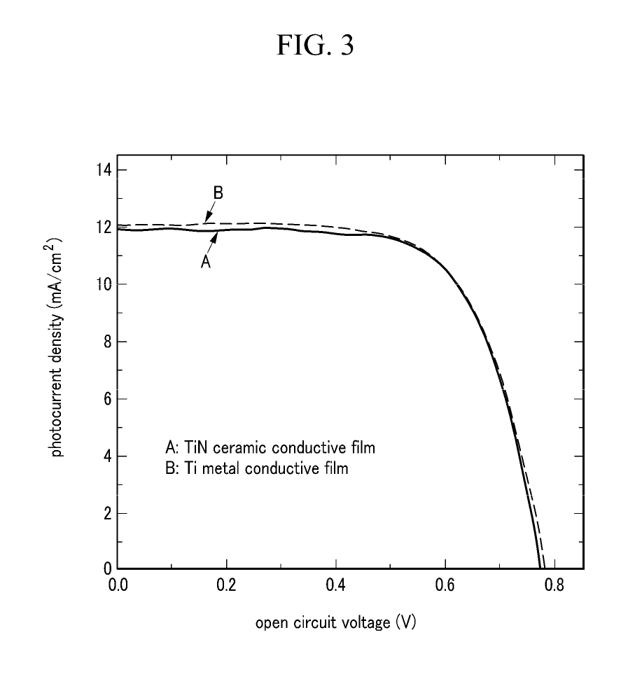

For each dye-sensitized solar cell prepared in Example 1 and Comparative Example 1, open circuit voltage, photocurrent density, energy conversion efficiency, and fill factor were measured as follows, and the results are summarized in the following Table 1 and FIG. 3.

(1) Open circuit voltage (V) and Photocurrent density (mA/cm²):

Open circuit voltage and photocurrent density were measured with Keithley SMU2400.

(2) Energy conversion efficiency (%) and Fill factor (%):

Energy conversion efficiency was measured with 1.5AM 100 mW/cm² solar simulator (consisting of Xe lamp [1600W, YAMASHITA DENSO], AM1.5 filter, and Keithley SMU2400), and fill factor was calculated using the obtained conversion efficiency and the following Equation.

$$Fill factor ( \% ) = \frac{( J \times V ) max}{Jsc \times Voc} \times 100 \qquad [ Equation ]$$

wherein J is a y-axis value of a conversion efficiency curve, V is an x-axis value of a conversion efficiency curve, and J_{sc} and V_{oc} are intercepts of each axis.

TABLE 1

| | | Open | | | | |
|---|---|---|---|---|---|---|
| | | circuit | Photocurrent | Fill | Conversion | Thickness of |
| | Conductive | voltage | density | factor | efficiency | metal oxide |
| | film | (V) | (mA/cm²) | (%) | (%) | (μm) |
| Example 1 | TiN- | 0.773 | 11.91 | 68.9 | 6.35 | 8.0 |
| | ceramic | | | | | |
| Comparative | Ti- | 0.783 | 12.09 | 67.1 | 6.36 | 8.1 |
| Example 1 | metal | | | | | |

As shown in Table 1 and FIG. 3, the dye-sensitized solar cells as Example 1 and Comparative Example 1 show similar performance in terms of photoelectric conversion efficiency.

However, it was confirmed that the dye-sensitized solar cell of Example 1 achieved higher performance in terms of fill factor, compared with Comparative Example 1. The reason why the dye-sensitized solar cell of Example 1 was used the photo-electrode comprising the conductive film that was formed with a TiN ceramic retaining a high level of electrical conductivity, and being a porous type, could have smooth movement of electrolyte.

### Experiment 2

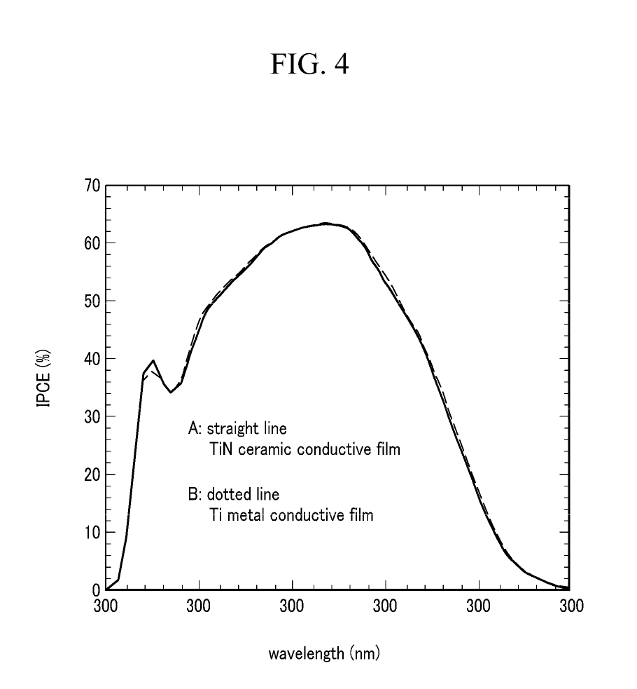

IPCE (incident photon-to-current conversion efficiency) of dye-sensitized solar cells prepared in Example 1 and Comparative Example 1 were measured, and the results are illustrated in FIG. 4.

As shown in FIG. 4, the dye-sensitized solar cells as Example 1 and Comparative Example 1 show similar performance in terms of IPCE for a wavelength. Thus, it was confirmed that the TiN ceramic has application possibilities to a conductive film of the photo-electrode for a dye-sensitized solar cell.

### Experiment 3

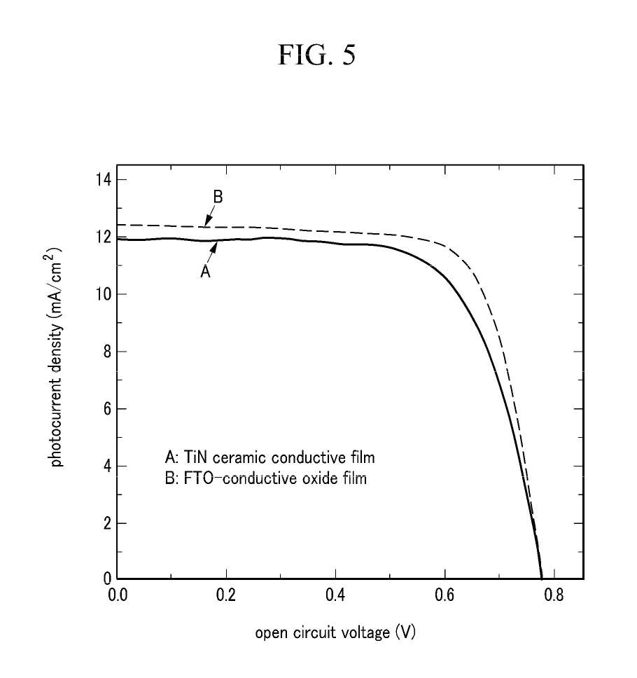

For each dye-sensitized solar cell prepared in Example 1 and Comparative Example 2, open circuit voltage, photocurrent density, energy conversion efficiency, and fill factor were measured as follows, and the results are summarized in the following Table 2 and FIG. 5.

TABLE 2

| | | Open | | | | |
|---|---|---|---|---|---|---|
| | | circuit | Photocurrent | Fill | Conversion | Thickness of |
| | Conductive | voltage | density | factor | efficiency | metal oxide |
| | film | (V) | (mA/cm²) | (%) | (%) | (μm) |
| Example 1 | TiN- | 0.773 | 11.91 | 68.9 | 6.35 | 8.0 |
| | ceramic | | | | | |
| Comparative | FTO- | 0.771 | 12.42 | 73.1 | 7.00 | 7.8 |
| Example 2 | oxide | | | | | |

As shown in Table 2 and FIG. 5, it was confirmed that the dye-sensitized solar cell of Comparative Example 2 achieved higher performance in terms of photocurrent density, fill factor, and photoelectric conversion efficiency compared with Example 1.

As shown in Table 2 and FIG. 5, the photoelectric conversion efficiency of Example 1 did not attain the top value known commonly.

However, it was confirmed that the dye-sensitized solar cell of Example 1 comprising the conductive film formed with the TiN ceramic was improved the photoelectric performance, considering that the thickness of the metal oxide film was thinner than the oxide electrode of the best mode, even though the result of Experiment 3 was low than Comparative Example 2 with the transparent conductive oxide (FTO) as the substrate.

### Experiment 4

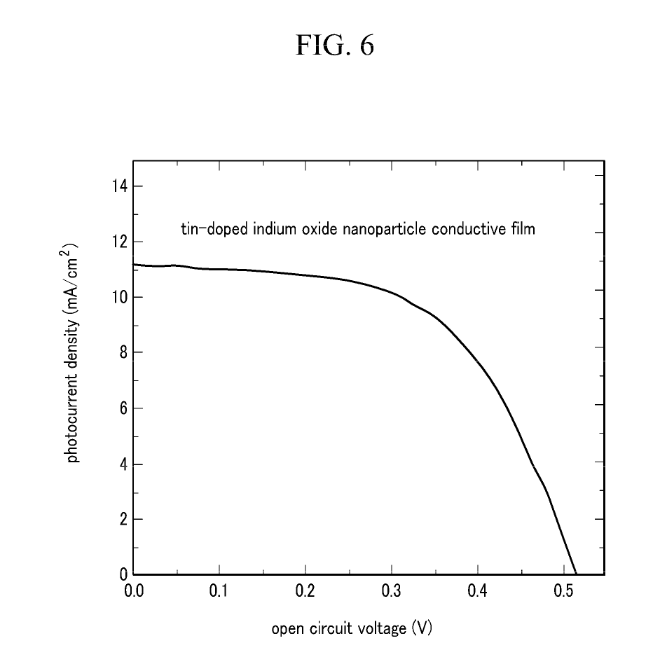

For each dye-sensitized solar cell prepared in Example 2, open circuit voltage, photocurrent density, energy conversion efficiency, and fill factor were measured as follows, and the results are summarized in the following Table 3 and FIG. 6.

TABLE 3

| | | Open | | | | |
|---|---|---|---|---|---|---|
| | | circuit | Photocurrent | Fill | Conversion | Thickness of |
| | Conductive | voltage | density | factor | efficiency | metal oxide |
| | film | (V) | (mA/cm²) | (%) | (%) | (μm) |
| Example 2 | tin-doped | 0.516 | 11.18 | 56.7 | 3.27 | 7.5 |
| | indium oxide | | | | | |

As shown in Table 3 and FIG. 6, the photoelectric conversion efficiency of Example 2 did not attain the top value known commonly. However, it was confirmed that the dye-sensitized solar cell of Example 2 has a possibility of improving photoelectric conversion efficiency through optimization, and shows application possibilities of tin-doped indium oxide nano-particles to the conductive film of the photo-electrode using spin-coating.

A number of exemplary embodiments have been described above. Nevertheless, it will be understood that various modifications may be made. For example, suitable results may be achieved if the described techniques are performed in a different order and/or if components in a described system, architecture, device, or circuit are combined in a different manner and/or replaced or supplemented by other components or their equivalents. Accordingly, other implementations are within the scope of the following claims.

What is claimed is:

1. A photo-electrode of a dye-sensitized solar cell, comprising:
a transparent substrate;
a porous membrane having metal oxide nano-particles adsorbed in a photosensitive dye; and
a conductive non-metal film,
wherein the porous membrane is arranged and contacted between the transparent substrate and the conductive non-metal film.

2. The photo-electrode according to claim 1, wherein the photo-electrode comprises:
the transparent substrate;
the porous membrane comprising the metal oxide nano-particles absorbed dyes that is formed on a part or the total surface of the transparent substrate; and
the conductive non-metal film formed on the porous membrane or on the porous membrane and the transparent substrate.

3. The photo-electrode according to claim 1, wherein the conductive non-metal film comprises at least one selected from the group consisting of metal nitrides, metal carbides, metal borides, metal oxides, carbon compounds, and conductive polymers.

4. The photo-electrode according to claim 3, wherein the metal nitrides comprise at least one selected from the group consisting of group IVB metal nitrides, group VB metal nitrides, group VIB metal nitrides, aluminum nitride, gallium nitride, indium nitride, silicon nitride, and germanium nitride.

5. The photo-electrode according to claim 4, wherein the metal nitrides comprise at least one selected from the group consisting of titanium nitride, zirconium nitride, hafnium nitride, niobium nitride, tantalum nitride, vanadium nitride, chromium nitride, molybdenum nitride, tungsten nitride, aluminum nitride, gallium nitride, indium nitride, silicon nitride, and germanium nitride.

6. The photo-electrode according to claim 3, wherein the metal carbides comprise at least one selected from the group consisting of group IVB metal carbides, group VB metal carbides, group VIB metal carbides, aluminum carbide, gallium carbide, indium carbide, silicon carbide, and germanium carbide.

7. The photo-electrode according to claim 6, wherein the metal carbides comprise at least one selected from the group consisting of titanium carbide, zirconium carbide, hafnium carbide, niobium carbide, tantalum carbide, vanadium carbide, chromium carbide, molybdenum carbide, tungsten carbide, aluminum carbide, gallium carbide, indium carbide, silicon carbide, and germanium carbide.

8. The photo-electrode according to claim 3, wherein the metal borides comprise at least one selected from the group consisting of group IVB metal borides, group VB metal borides, group VIB metal borides, aluminum boride, gallium boride, indium boride, silicon boride, and germanium boride.

9. The photo-electrode according to claim 8, wherein the metal borides comprise at least one selected from the group consisting of titanium boride, zirconium boride, hafnium boride, niobium boride, tantalum boride, vanadium boride, chromium boride, molybdenum boride, tungsten boride, aluminum boride, gallium boride, indium boride, silicon boride, and germanium boride.

10. The photo-electrode according to claim 3, wherein the metal oxides comprise at least one selected from the group consisting of tin oxide, stibium-doped tin oxide, niobium-doped tin oxide, fluorine-doped tin oxide, indium oxide, tin-doped indium oxide, zinc oxide, aluminum-doped zinc oxide, boron-doped zinc oxide, gallium-doped zinc oxide, hydrogen-doped zinc oxide, indium-doped zinc oxide, yttrium-doped zinc oxide, titanium-doped zinc oxide, silicon-doped zinc oxide, tin-doped zinc oxide, magnesium oxide, cadmium oxide, a magnesium-zinc (Mg—Zn) composite oxide, an indium-zinc (In—Zn) composite oxide, a copper-aluminum (Cu—Al) composite oxide, silver oxide, gallium oxide, a zinc-tin (Zn—Sn) composite oxide, titanium oxide(TIO₂), a zinc-indium-tin (Zn—In—Sn) composite oxide, nickel oxide, rhodium oxide, ruthenium oxide, iridium oxide, copper oxide, cobalt oxide, and tungsten oxide.

11. The photo-electrode according to claim 3, wherein the carbon compounds comprise at least one selected from the group consisting of activated carbon, graphite, carbon nanotubes, carbon black, and graphene.

12. The photo-electrode according to claim 3, wherein the conductive polymers comprise at least one selected from the group consisting of poly(3,4-ethylenedioxythiophene)-poly(styrenesulfonate), polyaniline-camphorsulfonic acid (CSA), pentacene, polyacetylene, poly(3-hexylthiophene), polysiloxane carbazole, polyaniline, polyethylene oxide, poly(1-methoxy-4-(0-disperse red 1)-2,5-phenylene-vinylene), polyindole, polycarbazole, polypyridazin, polyisothianaphthalene, polyphenylene sulfide, polyvinylpyridine, polythiophene, polyfluorene, polypyridine, polypyrrole, polysulfur nitride, and copolymers thereof.

13. The photo-electrode according to claim 1, wherein the average thickness of the conductive non-metal film is 1 to 1000 nm.

14. The photo-electrode according to claim 1, wherein the transparent substrate comprises at least one selected from the group consisting of transparent plastic substrates and a transparent glass substrate.

15. The photo-electrode according to claim 14, wherein the transparent substrate is manufactured by a polymer at least one selected from the group consisting of polyethylene terephthalate, polyethylenenaphthalate, polycarbonate, polypropylene, polyimide, tri-acetylcellulose, and polyethersulfone.

16. The photo-electrode according to claim 14, wherein the transparent substrate is manufactured by a modified organic silicate having a 3-D network structure by a hydrolysis and condensation reaction of an organic metal alkoxide of at least one selected from the group consisting of methyltriethoxysilane, ethyltriethoxysilane, and propyltriethoxysilane.

17. The photo-electrode according to claim 1, wherein the metal oxide nano-particles comprise at least one selected from the group consisting of titanium oxide, zirconium oxide, strontium oxide, zinc oxide, indium oxide, lanthanum oxide, vanadium oxide, molybdenum oxide, tungsten oxide, tin oxide, niobium oxide, magnesium oxide, aluminum oxide, yttrium oxide, scandium oxide, samarium oxide, gallium oxide, and a strontium-titanium (Sr—Ti) composite oxide.

18. The photo-electrode according to claim 1, wherein the average particle diameter of the metal oxide nano-particles is 1 to 500 nm.

19. The photo-electrode according to claim 1, wherein the photosensitive dye comprises at least one selected from the group consisting of an organic-inorganic complex dye and an organic dye, and a mixture comprising aluminum, platinum, palladium, europium, lead, iridium, ruthenium, and complexes thereof; and the band gap energy of the photosensitive dye is 1.55 to 3.1 eV.

20. A manufacturing method of a photo-electrode for dye-sensitized solar cell, comprising the steps of:
forming a porous membrane having metal oxide nano-particles on part or the total surface of a transparent substrate;
forming a conductive non-metal film on the porous membrane or on the porous membrane and the transparent substrate; and
absorbing a photosensitive dye on the porous membrane.

21. The method according to claim 20, wherein the step of forming a conductive non-metal film is conducted by sputter deposition, cathodic arc deposition, evaporation, e-beam evaporation, chemical vapor deposition, atomic layer deposition, electrochemical deposition, spin coating, spray coating, doctor blade coating, or screen printing.

22. The method according to claim 20, wherein the step of forming a porous membrane is conducted by coating a metal oxide nano-particle paste having metal oxide nano-particles, a binder resin, and a solvent on the transparent substrate, and heat-treating the transparent substrate.

23. The method according to claim 20, wherein the step of absorbing the photosensitive dye is conducted by immersing the transparent substrate formed with the porous membrane and the conductive non-metal film in a solution comprising the photosensitive dye for 1 to 48 hours.

24. A dye-sensitized solar cell comprising:
a photo-electrode according to claims 1;
a counter electrode arranged so as to face the photo-electrode; and
an electrolyte filled between the photo-electrode and the counter electrode.

25. The dye-sensitized solar cell according to claim 24, wherein the electrolyte comprises an aqueous solution of at least one selected from a redox derivative group consisting of iodine, bromine, cobalt, thiocyanate (SCN—), and selenocyanate (SeCn-).

26. The dye-sensitized solar cell according to claim 24, wherein the electrolyte comprises a polymer gel of at least one selected from the group consisting of polyvinylidenefluoride-co-polyhexafluoropropylene, polyacrylonitrile, polyethylene oxide, and polyalkylacrylate.

27. The dye-sensitized solar cell according to claim 24, wherein the electrolyte comprises a gel containing inorganic particles comprising at least one selected from the group consisting of silica and titanium dioxide.
